(19) United States
(12) Patent Application Publication
(10) Pub. No.: US 2025/0218747 A1
(43) Pub. Date: Jul. 3, 2025

(54) APPARATUS FOR AND METHOD OF PROCESSING SUBSTRATE

(71) Applicant: SEMES CO., LTD., Cheonan-si (KR)

(72) Inventors: Dong Hun KIM, Seongnam-si (KR); Hyun Jin KIM, Daegu (KR); Jung Hwan LEE, Ansan-si (KR); Jae Hyun CHO, Suwon-si (KR); Jun Ho LEE, Cheonan-si (KR); Beyoung Youn KOH, Cheonan-si (KR); Jin Young KIM, Suwon-si (KR)

(21) Appl. No.: 18/920,015

(22) Filed: Oct. 18, 2024

(30) Foreign Application Priority Data
Dec. 27, 2023 (KR) 10-2023-0192163

(51) Int. Cl. H01J 37/32; H01L 21/67

(52) U.S. Cl. CPC H01J 37/32697; H01J 37/32422; H01J 37/32651; H01J 2237/24564; H01L 21/67253

(57) ABSTRACT

An apparatus for and a method of processing a substrate are provided. The apparatus for processing a substrate includes a chamber having a processing space therein, a substrate support member disposed inside the chamber and supporting the substrate, an upper plate disposed above the substrate support member and having a plurality of through-holes, a sensor unit disposed inside the upper plate and measuring an induced electromotive force value generated in a measurement through-hole included in the plurality of through-holes, and a detection unit detecting an amount of ions passing through the measurement through-hole based on the induced electromotive force value.

### CROSS-REFERENCE TO RELATED APPLICATION(S)

This application claims benefit of priority to Korean Patent Application No. 10-2023-0192163 filed on Dec. 27, 2023 in the Korean Intellectual Property Office, the disclosure of which is incorporated herein by reference in its entirety.

### BACKGROUND

### 1. Field

The present disclosure relates to an apparatus for and a method of processing a substrate.

### 2. Description of Related Art

Plasma refers to matter in a gaseous state separated into ions, radicals, electrons, and the like at high temperatures. Plasma is generated by very high temperatures, strong electric fields, or RF electromagnetic fields.

A semiconductor device manufacturing process may include a process of etching the surface of a substrate to form a required pattern on the substrate. The etching process may be performed by ions or radicals contained in the plasma, colliding with or reacting with a thin film formed on the substrate.

To control the substrate processing process using plasma, it is necessary to understand the distribution information of plasma in the chamber. To observe plasma in the chamber, there are a method of indirectly observing plasma through the optical spectrum emitted from the plasma using an Optical Emission Spectroscopy (OES) sensor, and an observation method of directly inserting a probe into the space in which the plasma is formed.

The method of indirectly observing plasma through the optical spectrum has low accuracy of observation values, and the method of directly inserting a probe has the problem of interference with the plasma.

### SUMMARY

An aspect of the present disclosure is to provide an apparatus for and a method of processing a substrate, in which plasma distribution information may be monitored without causing interference with plasma.

An aspect of the present disclosure is to provide an apparatus for and a method of processing a substrate, in which the amount of ions may be detected by measuring an induced electromotive force value generated by ions passing through a through-hole of an upper plate using a sensing member disposed in a containment structure inside the upper plate and linearizing the induced electromotive force value using an integrator circuit.

An aspect of the present disclosure is to provide an apparatus for and a method of processing a substrate, in which an induced electromotive force value generated by ions passing through through-holes disposed in different locations in an upper plate may be measured and plasma distribution information may be monitored within a chamber based on the amount of ions in each location in a processing space.

According to embodiments, the following apparatus for processing a substrate and method of processing a substrate are provided.

According to an aspect of the present disclosure, an apparatus for processing a substrate includes a chamber having a processing space therein, a substrate support member disposed inside the chamber and supporting the substrate, an upper plate disposed above the substrate support member and having a plurality of through-holes, a sensor unit disposed inside the upper plate and measuring an induced electromotive force value generated in a measurement through-hole included in the plurality of through-holes, and a detection unit detecting an amount of ions passing through the measurement through-hole based on the induced electromotive force value.

According to an aspect of the present disclosure, a method of processing a substrate includes generating plasma in a processing space within a chamber, measuring an induced electromotive force value generated in a through-hole of an upper plate disposed at an upper portion within the chamber, and detecting an amount of ions passing through the through-hole based on the induced electromotive force value. The measuring the induced electromotive force value uses a sensing member disposed within the upper plate.

According to an aspect of the present disclosure, an apparatus for processing a substrate includes a chamber having a processing space therein, an upper plate disposed in an upper portion of the chamber and having a plurality of through-holes, a plasma generation unit supplying processing gas to the processing space and generating plasma from the processing gas above the upper plate, a substrate support member disposed below the upper plate and supporting a substrate, a sensor unit including a sensing member disposed inside the upper plate and a shielding member shielding the sensing member, and measuring an induced electromotive force value generated in a measurement through-hole included in the plurality of through-holes, and a detection unit including an integrator circuit connected to an output node of the sensing member and detecting an amount of ions passing through the measurement through-hole based on the induced electromotive force value.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 illustrates an apparatus for processing a substrate according to an embodiment;

FIG. 2A is an example diagram illustrating induced electromotive force due to movement of ions;

FIG. 2B illustrates a partial configuration of an apparatus for processing a substrate according to an embodiment;

FIG. 2C illustrates a partial configuration of an apparatus for processing a substrate according to an embodiment;

FIG. 3 schematically illustrates a partial configuration of an apparatus for processing a substrate according to an embodiment;

FIG. 4 schematically illustrates a partial configuration of an apparatus for processing a substrate according to an embodiment;

FIG. 5 is a flowchart of a method of processing a substrate according to an embodiment; and

FIG. 6 illustrates an apparatus for processing a substrate according to another embodiment.

### DETAILED DESCRIPTION

Hereinafter, with reference to the attached drawings, embodiments will be described in detail so that those skilled in the art may easily practice the present disclosure. However, when describing example embodiments of the present disclosure in detail, if it is determined that a detailed description of related known functions or configurations may unnecessarily obscure the gist of the present disclosure, the detailed description thereof will be omitted. In addition, the same symbols are used throughout the drawings for parts that perform similar functions and actions. In addition, in this specification, the terms ‘on,’ ‘upper portion,’ ‘upper surface,’ ‘below,’ ‘lower portion,’ ‘lower surface,’ ‘lower side,’ ‘side,’ ‘side surface’, and the like are based on the drawings, and in reality, may vary depending on the direction in which the elements or components are disposed.

In addition, throughout the specification, when a part is said to be ‘connected’ to another part, this includes not only cases in which it is ‘directly connected’, but also cases in which it is ‘indirectly connected’ with another element therebetween. In addition, ‘including’ a certain component means that other components may be included, rather than excluding other components, unless otherwise specifically stated.

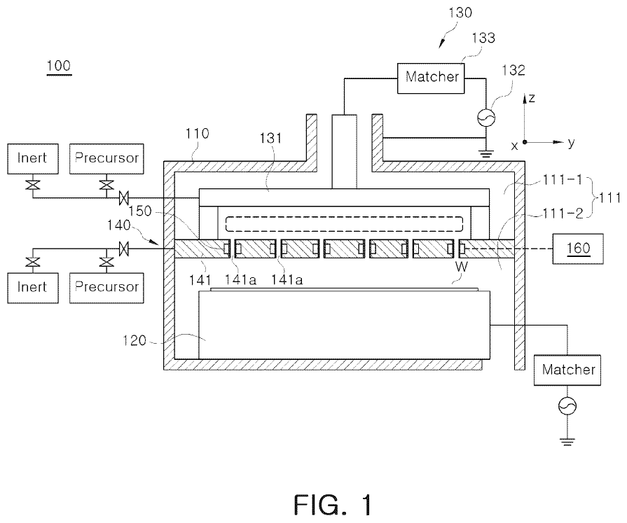

FIG. 1 illustrates an apparatus for processing a substrate according to an embodiment. Referring to FIG. 1, an apparatus 100 for processing a substrate may include a chamber 110, a substrate support member 120, a plasma generation unit 130, an upper plate 140, a sensor unit 150, and a detection unit 160.

The apparatus 100 for processing a substrate may perform processing on a substrate (W) using plasma. The processing on the substrate (W) may include, for example, an etching process.

A processing space 111 may be formed inside the chamber 110. The processing space 111 may be an environment that may be controlled to an appropriate temperature and pressure to perform processing on the substrate (W).

The substrate support member 120 may be disposed inside the chamber 110. The substrate support member 120 may include a substrate support surface that supports the substrate (W) and adsorbs and fixes the substrate (W).

The substrate support member 120 may be applied with a direct current voltage and adsorb the substrate (W) by electrostatic force. In addition, the substrate support member 120 may be controlled to have a preset temperature to control processing of the substrate (W).

The plasma generation unit 130 may generate plasma in the processing space 111. The plasma generation unit 130 may include an upper electrode 131, a voltage generation unit 132, and a matcher 133.

The voltage generation unit 132 may generate a high-frequency voltage for generating plasma. The high-frequency voltage generated by the voltage generation unit 132 may be applied to the upper electrode 131.

When the high-frequency voltage is applied to the upper electrode 131, plasma may be generated from the processing gas supplied to a first space 111-1.

The processing space 111 may include the first space 111-1 where plasma is generated and a second space 111-2 where processing of the substrate (W) is performed. The first space 111-1 and the second space 111-2 may be partitioned by the upper plate 140.

The upper plate 140 may be disposed above the substrate support member 120 in the upper portion of the chamber 110.

The upper plate 140 may include a showerhead 141 having a plurality of through-holes 141a. The plurality of through-holes 141a may be formed to penetrate through the showerhead 141 in a vertical direction.

For example, radicals of plasma or one or more gases may be provided to the substrate (W) disposed downward through the plurality of through-holes 141a.

The sensor unit 150 may be disposed inside the upper plate 140. The sensor unit 150 may measure an induced electromotive force value generated in a measurement through-hole included in the plurality of through-holes 141a.

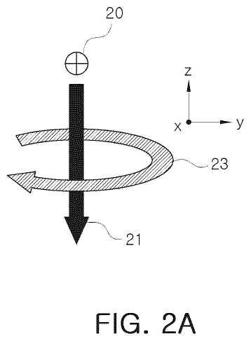

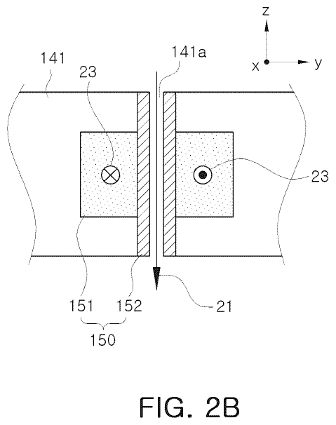

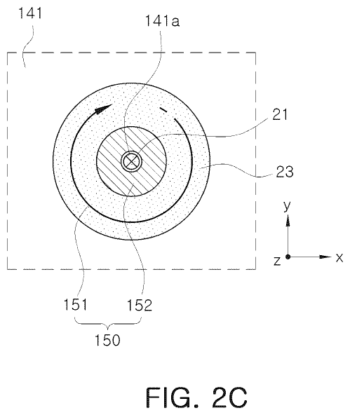

FIG. 2A is an example diagram illustrating induced electromotive force according to the movement of ions. As illustrated in FIG. 2A, as ion particles 20 move in one direction, an alternating current 21 dependent on a high frequency is generated, and a magnetic field 23 may be generated by the alternating current 21.

In the present disclosure, the induced electromotive force value generated by the ion particles 20 passing through the upper plate 140 may be measured using the sensor unit 150 disposed in the upper plate 140, and based thereon, the ion amount and plasma distribution information may be sequentially derived.

FIG. 2B and FIG. 2C are enlarged views of the configuration of the sensor unit 150 included in the apparatus for processing a substrate according to an embodiment. FIG. 2B illustrates a cross-sectional view of a portion of a showerhead 141 in which the sensor unit 150 is disposed, and FIG. 2C illustrates a cross-sectional view of a portion of the showerhead 141 in which the sensor unit 150 is disposed.

In detail, the sensor unit 150 may include a sensing member 151 and a shielding member 152.

The sensing member 151 may be disposed around the through-hole 141a and may have an annular pillar shape having a height value less than the thickness of the showerhead 141.

The shielding member 152 may be disposed around the through-hole 141a and may have an annular pillar shape having a height value equal to the thickness of the showerhead 141. The shielding member 152 may be disposed between the through-hole 141a and the sensing member 151.

The sensing member 151 may be disposed so that the upper surface, lower surface, and outer side surface thereof are covered by the showerhead 141, and the inner side surface of the sensing member 151 is covered by the shielding member 152. Therefore, the sensing member 151 may be disposed so as not to be directly exposed to ions or plasma.

The sensor unit 150 has a structure in which the sensing member 151 is containment-contained by the upper plate 140, for example, the showerhead 141 and the shielding member 152, and may thus detect the change in magnetic field according to the movement of ions without interfering with the plasma.

As illustrated in FIG. 2B and FIG. 2C, as ions move through the through-hole 141a, the alternating current 21 and the magnetic field 23 may be generated. The sensing member 151 may measure the induced electromotive force value generated by the magnetic field 23.

The detection unit 160 may detect the amount of ions passing through the measurement penetration hole based on the induced electromotive force value measured by the sensor unit 150.

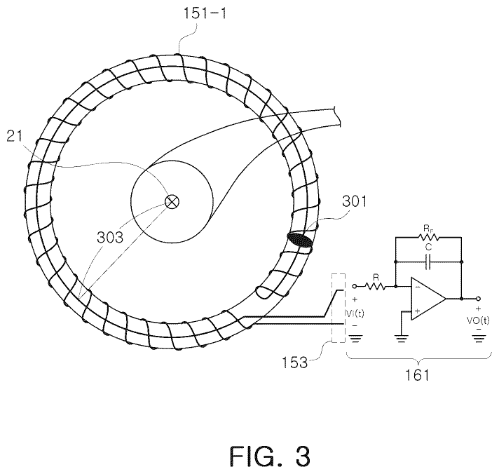

Referring to FIG. 3, the sensing member 151 may include a toroidal coil 151-1 disposed to surround the penetration hole 141a.

The sensing member 151 may measure the induced electromotive force value based on the number of turns of the toroidal coil 151-1, the cross-sectional area 301 of the toroidal coil 151-1, and the diameter 303 of the toroidal coil 151-1.

For example, when the number of turns of the toroidal coil 151-1 is N, the cross-sectional area 301 of the toroidal coil 151-1 is A, and the diameter 303 of the toroidal coil 151-1 is r, the induced electromotive force value (vi (t)) measured by the sensor unit 150 may be expressed as in mathematical expression 1. In mathematical expression 1, μ₀ is a permeability constant, which may be 4π*10\hat{ }(−7) H/m.

$${v}_{i} ( t ) = - \frac{AN {μ}_{0}}{2 π r} \frac{di ( t )}{dt} \qquad [ Mathematical Expression 1 ]$$

The detection unit 160 may include an integrator circuit 161 connected to an output node 153 of the sensor unit 150. The integrator circuit 161 may include an operational amplifier, a first resistor, a second resistor, and a capacitor.

The detection unit 160 may linearize the induced electromotive force value based on the magnitude of the first resistor, the magnitude of the second resistor, and the size of the capacitor of the integrator circuit 161.

For example, when the magnitude of the first resistor is R, the magnitude of the second resistor is RE, and the size of the capacitor is C, the output (vₒ(s)) of the integrator circuit 161 that receives the induced electromotive force value (vᵢ(t)) may be expressed as in Mathematical Expression 2.

$${v}_{o} ( s ) = - \frac{1}{RC} \frac{{v}_{i} ( s )}{s + \frac{1}{{R}_{F} C}} = \frac{AN {μ}_{0}}{2 π rRC} \frac{s}{s + \frac{1}{{R}_{F} C}} i ( s ) \qquad [ Mathematical Expression 2 ]$$

As illustrated in the mathematical expression 2, the output (vₒ(s)) of the integrator circuit 161 has a proportional relationship with the current (i(s)), and thus, the induced electromotive force value may be linearized through the integrator circuit 161.

The detection unit 160 may detect the amount of ions passing through the through-hole 141a based on the result of linearizing the induced electromotive force value. Since the movement of ions may appear as an AC current that depends on a high frequency, the detection unit 160 may detect the amount of ions based on the output of the integrator circuit 161 that is proportional to the magnitude of the AC current 21.

Referring again to FIG. 1, the sensing member 151 and the shielding member 152 may be disposed around a plurality of measurement through-holes that are disposed in different locations among the plurality of through-holes 141a. The sensing member 151 may measure the induced electromotive force value generated in the plurality of measurement through-holes.

The detection unit 160 may detect the ion amount for each position in the processing space 111 based on the induced electromotive force value generated in the plurality of measurement through-holes. The apparatus 100 for processing a substrate may further include a monitoring unit that monitors the plasma distribution information of the processing space 111 based on the ion amount for each position in the processing space 111.

For example, in the case where the plurality of measurement through-holes include a first measurement through-hole and a second measurement through-hole, the sensing member 151 may include a first sensing member disposed around the first measurement through-hole and a second sensing member disposed around the second measurement through-hole. In this case, the detection unit 160 may include a first integrator circuit connected to the first sensing member and linearizing the induced electromotive force value measured by the first sensing member, and a second integrator circuit connected to the second sensing member and linearizing the induced electromotive force value measured by the second sensing member.

Meanwhile, in another example, the sensor unit 150 may further include a first output node connected to the first sensing member and a second output node connected to the second sensing member. In this case, the detection unit 160 may further include a switching element connecting the integrator circuit to one of the first output node and the second output node.

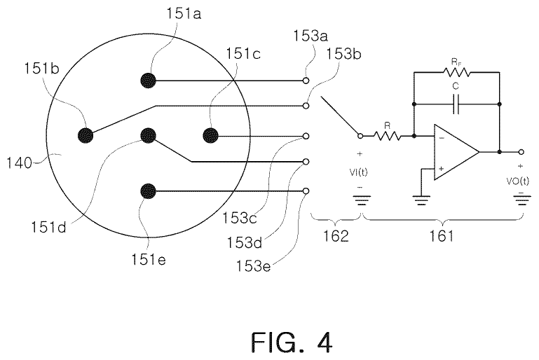

FIG. 4 schematically illustrates a plurality of sensing members 151a to 151e disposed around a plurality of measurement through-holes in an apparatus 100 for processing a substrate according to an embodiment. The plurality of sensing members 151a to 151e may be implemented by the sensing member 151 illustrated in FIG. 2B and FIG. 2C.

A plurality of sensing members 151a to 151e may be connected to a plurality of output nodes 153a to 153e that output the induced electromotive force values measured respectively thereby.

As illustrated in FIG. 4, the detection unit 160 may include one integrator circuit 161 and a switching element 162. The switching element 162 may be controlled to connect one of the plurality of output nodes 153a to 153e to the integrator circuit 161.

The detection unit 160 may linearize the induced electromotive force value measured by the sensing member corresponding to the output node connected to the integrator circuit 161 by the switching element 162.

In addition, the detection unit 160 may control the switching element 162 to be switched at a switching time interval determined based on the time constant of the integrator circuit 161.

The switching time interval may be determined so that the time constant (τ=R_{F}C) of the integrator circuit 161 has a value smaller than the switching time interval. In addition, to identify the change information of the plasma, when the number of the plurality of sensing members is N, the switching period (Nτ) may be set to be shorter than the change time of the plasma.

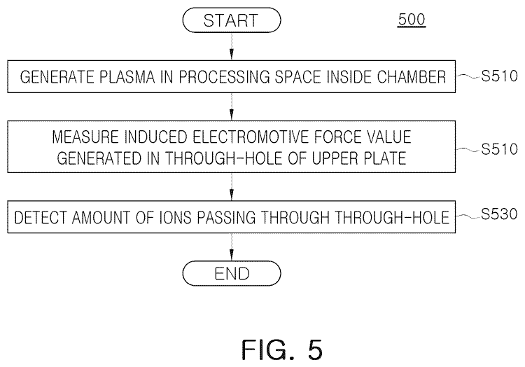

FIG. 5 is a flowchart of a method of processing a substrate according to an embodiment. Referring to FIG. 5, a method (500) of processing a substrate may include an operation (S510) of generating plasma in a processing space inside a chamber, an operation (S520) of measuring an induced electromotive force value generated in a through-hole of an upper plate, and an operation (S530) of detecting an amount of ions passing through the through-hole.

In the operation (S520) of measuring an induced electromotive force value, the induced electromotive force value may be measured by a sensing member disposed inside the upper plate. The sensing member may include a toroidal coil disposed to surround the through-hole.

The operation (S520) of measuring the induced electromotive force value may measure the induced electromotive force value generated in the through-hole based on the number of turns of the toroidal coil, the cross-sectional area of the toroidal coil, and the diameter of the toroidal coil.

The operation (S530) of detecting the amount of ions may include an operation of inputting the induced electromotive force value into an integrator circuit including a first resistor, a second resistor, and a capacitor, and an operation of linearizing the induced electromotive force value based on the magnitude of the first resistor, the magnitude of the second resistor, and the size of the capacitor.

The method (500) of processing a substrate may further include an operation of monitoring plasma distribution information of the processing space based on the amount of ions at each location.

For example, in the case where the plurality of measurement through-holes formed in the upper plate include a first measurement through-hole and a second measurement through-hole, the sensing member may include a first sensing member disposed around the first measurement through-hole and a second sensing member disposed around the second measurement through-hole.

The operation (S520) of measuring the induced electromotive force value may include an operation of measuring a first induced electromotive force value generated in the first measurement through-hole using the first sensing member, and an operation of measuring a second induced electromotive force value generated in the second measurement through-hole using the second sensing member.

The operation (S530) of detecting the amount of ions may include an operation of inputting a first induced electromotive force value into an integrator circuit, an operation of switching an input terminal of the integrator circuit between an output node of a first sensing member and an output node of a second sensing member, and an operation of inputting a second induced electromotive force value into the integrator circuit.

The operation of switching the input terminal of the integrator circuit between the output node of the first sensing member and the output node of the second sensing member may include an operation of switching the input terminal of the integrator circuit at a time interval determined based on a time constant of the integrator circuit.

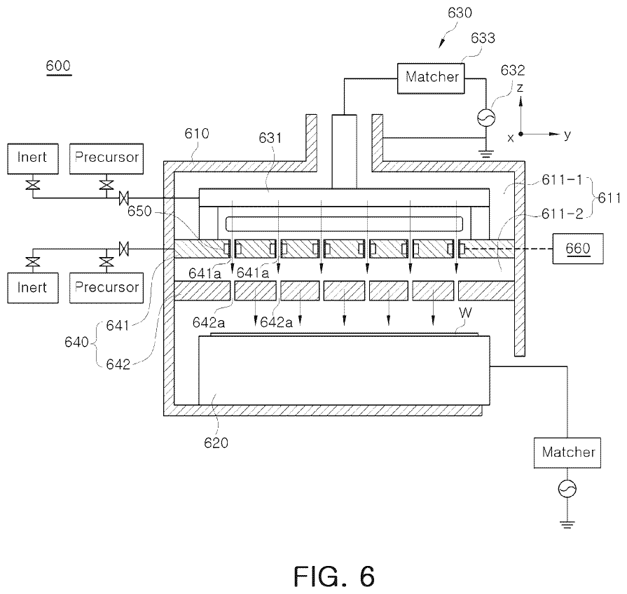

FIG. 6 illustrates an apparatus for processing a substrate according to another embodiment. Referring to FIG. 6, an apparatus 600 for processing a substrate may include a chamber 610, a substrate support member 620, a plasma generation unit 630, an upper plate 640, a sensor unit 650, and a detection unit 660. Hereinafter, descriptions of the same parts as the apparatus 100 for processing a substrate illustrated in FIG. 1 among the configurations of the apparatus 600 for processing a substrate of FIG. 6 will be omitted, and the configurations that are different from the apparatus 100 for processing a substrate will be described.

The upper plate 640 of the apparatus 600 for processing a substrate may be installed above the substrate support member 620 in the upper portion of the chamber 610. The upper plate 640 may include an ion blocking plate 641 and a showerhead 642.

The ion blocking plate 641 may be disposed above the showerhead 642 and may have a plurality of first through-holes 641a.

The showerhead 642 may be disposed below the ion blocking plate 641 to face the ion blocking plate 641 with a predetermined gap therebetween. The showerhead 642 may have a plurality of second through-holes 642a.

The sensor unit 650 may be disposed to surround at least some of the plurality of first through-holes 641a inside the ion blocking plate 641. The sensor unit 650 may measure an induced electromotive force value generated by the movement of ions in at least some of the plurality of first through-holes 641a.

The detection unit 660 may detect the amount of ions passing through at least some of the plurality of first through-holes 641a based on the induced electromotive force value measured by the sensor unit 650.

In addition, in describing the present disclosure, ‘˜part,’ ‘portion,’ ‘member,’ or ‘unit’ may be implemented in various manners, for example, by a processor, program instructions executed by a processor, a software module, a microcode, a computer program product, a logic circuit, an application-specific integrated circuit, firmware, or the like.

The contents of the method disclosed in the embodiment of the present disclosure may be directly implemented by a hardware processor, or may be implemented and performed by a combination of hardware and software modules among the processors. The software module may be stored in a storage medium of the related art, such as a random access memory, a flash memory, a read-only memory, a programmable read-only memory, an electrically erasable programmable memory, a register, and the like. The storage medium is located in the memory, and the processor reads the information stored in the memory and combines the information with the hardware to complete the contents of the above-described method. To avoid duplication, a detailed description is omitted here.

In the implementation process, each content of the above-described method may be completed by a logical integrated circuit of the hardware among the processors or an instruction in the form of software.

For example, those skilled in the art will recognize that each illustrative unit and algorithm step described in the embodiments disclosed herein may be obtained by combining electronic hardware or a combination of computer software and electronic hardware. Whether such a function is performed in a hardware manner or in a software manner is determined by the specific application and design constraints of the technical solution. Those skilled in the art may implement the described function using different methods for respective specific applications, but such implementation should not be considered as being outside the scope of the present disclosure.

In some embodiments provided in the present disclosure, it should be understood that the disclosed devices and methods may be obtained in other manners. For example, the device embodiments described above are merely examples, and for example, the division of the units is merely a kind of logical functional division, and other division methods may exist in actual implementation. For example, multiple units or assemblies may be combined or integrated into another system, or some features may be ignored or not performed. On the other hand, the coupling or direct coupling or communication connection between each other illustrated or discussed may be an indirect coupling or communication connection through some interface, device or unit, and may be electrical, mechanical or other forms.

The units described as separate components above may be physically separate, and the components illustrated as units may or may not be physical units, for example, may be located in one place or distributed in multiple network units. Some or all of the units may be selected according to actual needs to implement the solution of the present embodiment.

For example, respective functional units in respective embodiments of the present disclosure may be integrated into one processing unit, each unit may exist alone, or two or more units may be integrated into one unit.

If the above function is implemented in the form of a software functional unit and sold or used as an independent product, the function may be stored in one computer-readable storage medium. Based on this understanding, the technical solution of the present disclosure, which is essential or contributes to the prior art, or a part of the technical solution, may be implemented in the form of a software product, and the computer software product is stored in one storage medium and includes a few instructions to cause one computer device (which may be a personal computer, a server, a network device, or the like) to perform all or part of the operations of the method described in each embodiment of the present disclosure. The storage medium described above includes various media capable of storing program codes, such as a USB memory, a mobile hard disk, a read-only memory (ROM), a random access memory (RAM), a magnetic disk, a CD-ROM, or the like.

As set forth above, according to an embodiment, an apparatus for and a method of processing a substrate in which plasma distribution information may be monitored without causing interference with plasma may be provided.

In an embodiment, there may be provided an apparatus for and a method of processing a substrate in which the amount of ions may be detected by measuring an induced electromotive force value generated by ions passing through a through-hole of an upper plate using a sensing member disposed in a containment structure inside an upper plate and linearizing the induced electromotive force value using an integrator circuit.

In an embodiment, there may be provided an apparatus for and a method of processing a substrate in which an induced electromotive force value generated by ions passing through through-holes disposed in different locations of an upper plate may be measured and plasma distribution information may be monitored within a chamber based on the amount of ions at each location of a processing space.

While example embodiments have been illustrated and described above, it will be apparent to those skilled in the art that modifications and variations could be made without departing from the scope of the present disclosure as defined by the appended claims.

What is claimed is:

1. An apparatus for processing a substrate, comprising:
a chamber having a processing space therein;
a substrate support member disposed inside the chamber and supporting the substrate;
an upper plate disposed above the substrate support member and having a plurality of through-holes;
a sensor unit disposed inside the upper plate and measuring an induced electromotive force value generated in a measurement through-hole included in the plurality of through-holes; and
a detection unit detecting an amount of ions passing through the measurement through-hole based on the induced electromotive force value.

2. The apparatus of claim 1, wherein the sensor unit includes,
a sensing member disposed around the measurement through-hole and having a circular pillar shape with a height value less than a thickness of the upper plate; and
a shielding member disposed between the measurement through-hole and the sensing member and having a circular pillar shape with a height value equal to the thickness of the upper plate.

3. The apparatus of claim 2, wherein the sensing member includes a toroidal coil disposed to surround the measurement through-hole, and
an upper surface, a lower surface and an outer side surface of the sensing member are covered by the upper plate, and an inner side surface of the sensing member is covered by the shielding member.

4. The apparatus of claim 3, wherein the sensor unit measures the induced electromotive force value based on a number of turns of the toroidal coil, a cross-sectional area of the toroidal coil, and a diameter of the toroidal coil.

5. The apparatus of claim 4, wherein the detection unit includes an integrator circuit including a first resistor, a second resistor, and a capacitor, and the detection unit linearizes the induced electromotive force value based on a magnitude of the first resistor, a magnitude of the second resistor, and a size of the capacitor, and detects the amount of ions based on a linearized result.

6. The apparatus of claim 5, wherein the measurement through-hole includes a plurality of measurement through-holes disposed in different locations of the upper plate,
the sensor unit measures an induced electromotive force value generated in the plurality of measurement through-holes, and
the detection unit detects an ion amount for each location based on the induced electromotive force value generated in the plurality of measurement through-holes.

7. The apparatus of claim 6, further comprising a monitoring unit monitoring plasma distribution information of the processing space based on the ion amount for each location.

8. The apparatus of claim 6, wherein the plurality of measurement through-holes include a first measurement through-hole and a second measurement through-hole,
the sensing member includes a first sensing member disposed around the first measurement through-hole and a second sensing member disposed around the second measurement through-hole, and
the integrator circuit includes a first integrator circuit connected to the first sensing member and a second integrator circuit connected to the second sensing member.

9. The apparatus of claim 6, wherein the plurality of measurement through-holes include a first measurement through-hole and a second measurement through-hole,
the sensing member includes a first sensing member disposed around the first measurement through-hole and a second sensing member disposed around the second measurement through-hole,
the sensor unit further includes a first output node connected to the first sensing member and a second output node connected to the second sensing member, and
the detection unit further includes a switching element connecting one of the first output node and the second output node to the integrator circuit.

10. The apparatus of claim 9, wherein the detection unit switches the switching element between the first output node and the second output node at a time interval determined based on a time constant of the integrator circuit.

11. The apparatus of claim 1, wherein the upper plate includes:
an ion blocking plate having a plurality of first through-holes; and
a showerhead disposed below the ion blocking plate, to face the ion blocking plate with a predetermined gap therebetween, and having a plurality of second through-holes, and
the sensor unit is disposed to surround at least some of the plurality of first through-holes inside the ion blocking plate.

12. A method of processing a substrate, comprising:
generating plasma in a processing space within a chamber;
measuring an induced electromotive force value generated in a through-hole of an upper plate disposed at an upper portion within the chamber; and
detecting an amount of ions passing through the through-hole based on the induced electromotive force value,
wherein the measuring the induced electromotive force value uses a sensing member disposed within the upper plate.

13. The method of claim 12, wherein the sensing member includes a toroidal coil disposed to surround the through-hole, and
the measuring the induced electromotive force value includes measuring the induced electromotive force value based on a number of turns of the toroidal coil, a cross-sectional area of the toroidal coil, and a diameter of the toroidal coil.

14. The method of claim 13, wherein the detecting the amount of ions includes,
inputting the induced electromotive force value into an integrator circuit including a first resistor, a second resistor, and a capacitor; and
linearizing the induced electromotive force value based on a magnitude of the first resistor, a magnitude of the second resistor, and a size of the capacitor.

15. The method of claim 14, wherein the through-hole includes a plurality of measurement through-holes disposed in different locations of the upper plate,
the measuring the induced electromotive force value includes measuring the induced electromotive force value generated in the plurality of measurement through-holes, and
the detecting the amount of ions includes detecting an ion amount for each location based on the induced electromotive force value generated in the plurality of measurement through-holes.

16. The method of claim 15, further comprising monitoring plasma distribution information of the processing space based on the ion amount for each location.

17. The method of claim 15, wherein the plurality of measurement through-holes include a first measurement through-hole and a second measurement through-hole,
the sensing member includes a first sensing member disposed around the first measurement through-hole and a second sensing member disposed around the second measurement through-hole, and
the measuring the induced electromotive force value includes,
measuring a first induced electromotive force value generated in the first measurement through-hole using the first sensing member; and
measuring a second induced electromotive force value generated in the second measurement through-hole using the second sensing member.

18. The method of claim 17, wherein the detecting the ion amount further includes,
inputting the first induced electromotive force value to the integrator circuit;
switching an input terminal of the integrator circuit between an output node of the first sensing member and an output node of the second sensing member; and
inputting the second induced electromotive force value into the integrator circuit.

19. The method of claim 18, wherein the switching switches the input terminal of the integrator circuit at a time interval determined based on a time constant of the integrator circuit.

20. An apparatus for processing a substrate, comprising:
a chamber having a processing space therein;
an upper plate disposed in an upper portion of the chamber and having a plurality of through-holes;
a plasma generation unit supplying processing gas to the processing space and generating plasma from the processing gas above the upper plate;
a substrate support member disposed below the upper plate and supporting a substrate;
a sensor unit including a sensing member disposed inside the upper plate and a shielding member shielding the sensing member, and measuring an induced electromotive force value generated in a measurement through-hole included in the plurality of through-holes; and
a detection unit including an integrator circuit connected to an output node of the sensing member and detecting an amount of ions passing through the measurement through-hole based on the induced electromotive force value.
